(19) United States
(12) Patent Application Publication
(10) Pub. No.: US 2003/0092264 A1
(43) Pub. Date: May 15, 2003

(54) Substrate processing apparatus and method

(76) Inventors: Shinji Kajita, Tokyo (JP); Ichiro Katakabe, Tokyo (JP); Haruko Ohno, Tokyo (JP); Yuki Inoue, Tokyo (JP); Sachiko Kihara, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/261,670

(22) Filed: Oct. 2, 2002

(30) Foreign Application Priority Data
Oct. 3, 2001 (JP) 2001-307543

(51) Int. Cl. H01L 21/302; H01L 21/461

(52) U.S. Cl. 438/689

(57) ABSTRACT

There is provided a substrate processing apparatus and method which can uniformly increase the rate of processing of a substrate, e.g. etching or plating that takes place in the surface of a substrate, and which, when carrying out plating processing of a substrate, can form a plated film having a uniform film thickness easily and quickly. The substrate processing apparatus includes: a substrate holder 10 for holding and rotating a substrate W; and a heated fluid supply section 24 for bringing a heated fluid at a controlled temperature into contact with the substrate W, which is held and rotated by the substrate holder 10, so as to control the temperature of the substrate W.

### BACKGROUND OF THE INVENTION

1. Field of the Invention

This invention relates to a substrate processing apparatus and method, and more particularly to a substrate processing apparatus and method that effects heating of a substrate, such as a semiconductor wafer, thereby increasing substrate processing rates, e.g. rate of wet etching of a film or film-forming rate.

2. Description of the Related Art

In recent years, instead of using aluminum or aluminum alloys as a material for forming interconnection circuits on a substrate such as a semiconductor wafer, there is an eminent movement towards using copper (Cu) which has a low electric resistivity and high electromigration resistance. Copper interconnects are generally formed by filling copper into fine recesses formed in the surface of a substrate. There are known various techniques for forming such copper interconnects, including CVD, sputtering, and plating. According to any such technique, a copper film is formed in the substantially entire surface of a substrate, followed by removal of unnecessary copper by chemical mechanical polishing (CMP).

FIGS. 4A through 4C illustrate, in sequence of process steps, an example of forming such a substrate W having copper interconnects. As shown in FIG. 4A, an oxide film (insulating film) 2 of SiO₂ is deposited on a conductive layer 1a in which electronic devices are formed, which is formed on a semiconductor base 1. A contact hole 3 and a trench 4 for interconnects are formed in the oxide film 2 by the lithography/etching technique. Thereafter, a barrier layer 5 of TaN or the like is formed on the surface, and a seed layer 7 as an electric supply layer for electroplating is formed on the barrier layer 5.

Then, as shown in FIG. 4B, copper plating is performed onto the surface of the substrate W to fill the contact hole 3 and the trench 4 with copper and, at the same time, deposit a copper film 6 on the oxide film 2. Thereafter, the copper film 6 and the barrier layer 5 on the oxide film 2 are removed by chemical mechanical polishing (CMP) so as to make the surface of the copper film 6 filled in the contact hole 3 and the trench 4 for interconnects and the surface of the oxide film 2 lie substantially on the same plane. An interconnection composed of the copper film 6 as shown in FIG. 4C is thus formed.

The barrier layer 5 is formed so that it covers the substantially entire surface of the oxide film 2, and the seed layer 7 is formed so that it covers the substantially entire surface of the barrier layer 5. Accordingly, there are cases where the copper film as the seed layer is present in an edge portion (peripheral portion) of the substrate W, or the plated copper film remains unpolished in an edge portion of the substrate W. Further, there is also a case where copper or a copper salt adheres to the back surface of the substrate upon the formation of the seed layer or during the plating step. Such copper can easily diffuse into the insulating film in a semiconductor manufacturing process, e.g. in an annealing step, thereby deteriorating the insulating properties of the film, or can cause contamination during later transfer or processing of the substrate. It is therefore necessary to completely remove such copper. In this respect, it has been proposed to remove a conductive material such as copper, formed on or adhering to an edge portion of a substrate, by etching processing or the like. It is known that depending upon the laminate structure of a substrate, particles are generated in an edge portion of the substrate upon the processing of the edge portion with a chemical liquid.

As a method for effecting edge-etching processing of a substrate in which a copper (Cu) film, a ruthenium (Ru) film or the like as an interconnect or electrode material has been formed, there is known a method in which, while rotating the substrate, ultrapure water is supplied to the center of the substrate and, at the same time, an etching liquid for removing the interconnect or electrode material is supplied to an edge portion of the substrate, thereby etching and removing the unnecessary conductive material formed on or adhering to the edge portion of the substrate. In such an edge-etching processing, it is a conventional practice to raise the temperature of an etching liquid in order to increase the etching rate.

On the other hand, when forming a copper film 6 (see FIG. 4B) on the surface of a substrate by electroplating or electroless plating using an electroplating apparatus or electroless plating apparatus of the plating solution circulation type, it is widely practiced to control the temperature of a plating solution so as to control the film-forming rate.

However, when a highly volatile chemical liquid or a chemical liquid that is decomposable at high temperatures, for example, is used as an etching liquid, it is undesirable, in the light of safety and of burdens on the apparatus and on the environment, to raise the temperature of such a chemical liquid (etching liquid) and bring the heated chemical liquid into contact with a substrate to increase the etching rate. Further, when a substrate processing rate, e.g. etching rate or film-forming rate, is increased by heating of an etching liquid or by control of the temperature of a plating solution as in the above-described conventional techniques, for example, the following problems are encountered. Since a substrate is at room temperature at the initial stage of processing of the substrate, the temperature of the substrate does not become uniform over the entire surface, leading to unevenness of the substrate processing rate. Moreover, in the case of plating processing, it is difficult to equalize the film thickness of a plated film over the entire surface of the substrate.

### SUMMARY OF THE INVENTION

The present invention has been made in view of the above drawbacks in the related art. It is therefore an object of the present invention to provide a substrate processing apparatus and method which can uniformly increase the rate of processing of a substrate, e.g. etching or plating that takes place in the surface of a substrate, and which, when carrying out plating processing of a substrate, for example, can form a plated film having a uniform film thickness easily and quickly.

In order to achieve the above object, the present invention provides a substrate processing apparatus, comprising: a substrate holder for holding and rotating a substrate; and a heated fluid supply section for bringing a heated fluid at a controlled temperature into contact with the substrate, which is held and rotated by the substrate holder, so as to control the temperature of the substrate.

By thus bringing a heated fluid into contact with a substrate so as to control the temperature of the substrate itself, it becomes possible to keep the temperature of the entire substrate constant from the beginning of processing, thereby increasing the processing rate uniformly. Further, in the case of plating processing, since uniformity of the temperature of a substrate over the entire surface is enhanced, a plated film having a more uniform film thickness can be obtained.

A heated liquid may be used as the heated fluid. The heating of a substrate by a heated liquid makes it possible to control the temperature of the substrate without raising the temperature of a highly volatile chemical liquid or a chemical liquid that is decomposable at high temperatures. For example, a heated liquid may be supplied to the front surface of a substrate and a highly volatile chemical liquid or a chemical liquid that is decomposable at high temperatures may be supplied to the back surface of the substrate, thereby carrying out processing of the substrate while controlling the temperature of the substrate itself.

The heated liquid may be pure water. For example, by raising the temperature of pure water which is used for rinsing of a substrate, the temperature of the substrate itself can be controlled without raising the temperature of a highly volatile chemical liquid or a chemical liquid that is decomposable at high temperatures.

The substrate processing apparatus may further comprise a fluid supply section for supplying a fluid to an arbitrary region of the substrate held by the substrate holder. A fluid, for example an etching liquid for use in etching processing, is supplied to an arbitrary region of the substrate. The substrate can be heated without heating the etching liquid which may be a highly volatile chemical liquid or a chemical liquid that is decomposable at high temperatures.

The present invention also provides a substrate processing apparatus comprising a substrate holder for holding and rotating a substrate, the apparatus carrying out processing of the substrate by simultaneously bringing a plurality of fluids into contact with the substrate which is held and rotated by the substrate holder, wherein at least one of the plurality of fluids is a heated fluid and the remainder is a fluid nearly at room temperature or lower. The term “room temperature” herein refers to ambient temperature not involving heating or cooling.

The present invention provides a substrate processing method, comprising: carrying out processing of a substrate while controlling the temperature of the substrate by bring a heated fluid at a controlled temperature into contact with the substrate while holding and rotating the substrate.

The processing of the substrate may be edge-etching and/or substrate cleaning. Alternatively, the processing of the substrate may be plating.

The present invention also provides a substrate processing method, comprising: bringing a fluid nearly at room temperature or lower into contact with a substrate while rotating and holding the substrate to carry out processing of the substrate while, at the same time, bringing a heated fluid at a controlled temperature into contact with the substrate so as to control the temperature of the substrate.

### BRIEF DESCRIPTION OF THE DRAWINGS

FIG. 1 is a perspective view of a substrate processing apparatus according to a first embodiment of the present invention, which is utilized as an edge-etching apparatus;

FIG. 2 is a cross-sectional view schematically showing a substrate processing apparatus according to a second embodiment of the present invention, which is utilized as an electroless plating apparatus;

FIG. 3 is a diagram showing the general construction of a substrate processing system which is provided with the substrate processing apparatus (electroless plating apparatus) shown in FIG. 2;

FIGS. 4A through 4C are diagrams illustrating, is sequence of process steps, an example of the production of a substrate with copper interconnects;

FIG. 5 is a layout plan of a semiconductor manufacturing apparatus;

FIG. 6 is a diagram illustrating the flow of air in the semiconductor manufacturing apparatus shown in FIG. 5;

FIG. 7 is a diagram illustrating the flow of air in the respective areas of the semiconductor manufacturing apparatus shown in FIG. 5;

FIG. 8 is an outline view of the semiconductor manufacturing apparatus shown in FIG. 5 as disposed in a clean room;

FIG. 9 is a layout plan of another example of a semiconductor manufacturing apparatus;

FIG. 10 is a layout plan of still another example of a semiconductor manufacturing apparatus;

FIG. 11 is a layout plan of still another example of a semiconductor manufacturing apparatus;

FIG. 12 is a layout plan of still another example of a semiconductor manufacturing apparatus;

FIG. 13 is a layout plan of still another example of a semiconductor manufacturing apparatus;

FIG. 14 is a layout plan of still another example of a semiconductor manufacturing apparatus;

FIG. 15 is a layout plan of still another example of a semiconductor manufacturing apparatus;

FIG. 16 is a layout plan of still another example of a semiconductor manufacturing apparatus;

FIG. 17 is a layout plan of still another example of a semiconductor manufacturing apparatus;

FIG. 18 is a flow chart illustrating the process steps in the semiconductor manufacturing apparatus shown in FIG. 17;

FIG. 19 is a vertical sectional front view of an annealing unit; and

FIG. 20 is a horizontal sectional view of the annealing unit of FIG. 19.

### DETAILED DESCRIPTION OF THE PREFERRED EMBODIMENTS

Preferred embodiments of the present invention will now be described with reference to the drawings.

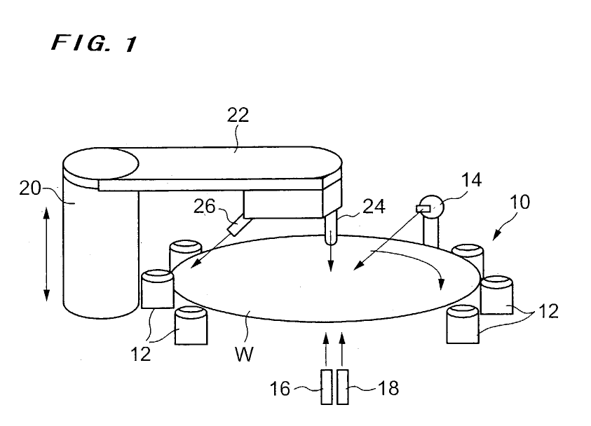

FIG. 1 shows a substrate processing apparatus according to a first embodiment of the present invention. The substrate processing apparatus is adapted for edge-etching processing of a substrate. The substrate processing apparatus includes a substrate holder 10 for holding a substrate W with its front surface facing upward and rotating the substrate W. The substrate holder 10 includes a plurality of rotating supports 12 which are disposed around the substrate W and can move inwardly. The rotating supports 12 are moved inwardly so as to hold the substrate W by putting the substrate W among the rotating supports 12, and the substrate W is allowed to rotate by the rotation of the rotating supports 12.

Positioned beside the substrate holder 10, there is provided a front surface nozzle 14 for supplying pure water, etc. to substantially the center of the front surface of the substrate W held by the substrate holder 10. Further, positioned below substantially the center of the back surface of the substrate W held by the substrate holder 10, there are provided vertically-oriented back surface nozzles 16, 18 for supplying pure water, a chemical liquid, etc. to substantially the center of the back surface of the substrate held by the substrate holder 10.

Furthermore, positioned beside the substrate holder 10, a vertically-movable and rotatable support shaft 20 is disposed vertically. A horizontally-extending pivot arm 22 is coupled at the base end to the upper end of the support shaft 20. On the free end side of the pivot arm 22, there are provide a center nozzle 24 for supplying pure water, a chemical liquid, etc. to substantially the center of the front surface of the substrate W held by the substrate holder 10, and an edge nozzle 26 for supplying a chemical liquid, etc. to a peripheral region (edge) of the front surface of the substrate W.

According to this embodiment, the center nozzle 24 is designed to function as a heated fluid supply section that supplies a heated fluid at a controlled temperature to the substrate W held by the substrate holder 10 to bring the heated fluid into contact with the substrate W, and the edge nozzle 26 is designed to function as a fluid supply section that supplies a chemical liquid, etc. to the substrate W.

More specifically, while the substrate W is held and rotated by the rotating supports 12 of the substrate holder 10, a heated fluid is supplied from the center nozzle (heated fluid supply section) 24 to the front surface of the substrate W, and the heated fluid supplied is forced to spread over the entire surface of the substrate by centrifugal force, whereby the whole substrate is heated uniformly and the temperature of the substrate can be controlled. Simultaneously with such operation, a chemical liquid, etc. is supplied from the edge nozzle 26 to a peripheral region of the substrate, thereby carrying out the processing such as edge-etching processing.

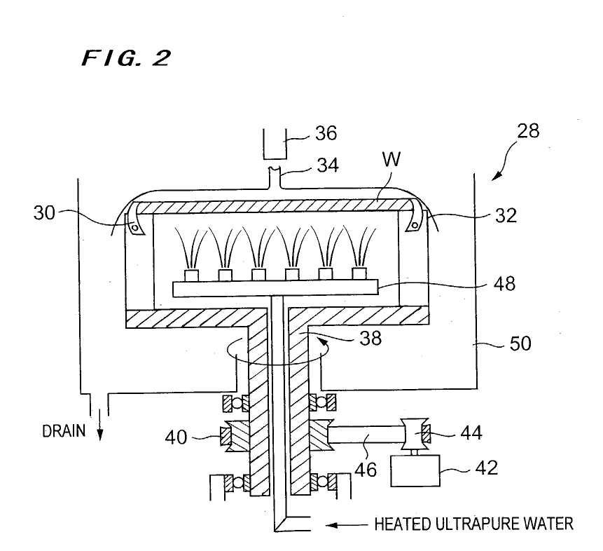

FIG. 2 shows a substrate processing apparatus according to a second embodiment of the present invention. The substrate processing apparatus is utilized as an electroless plating apparatus 28 for carrying out plating processing of the surface of a substrate W. The electroless plating apparatus 28 includes a rotatable substrate holder 32 for detachably holding a substrate W with its front surface facing upward by chucks 30, and a center nozzle 36 for supplying a plating solution 34 to the upper surface (to-be-plated surface) of the substrate W held by the substrate holder 32. The substrate holder 32 is coupled to the upper end of a main shaft 38. A timing belt 46 is stretched between a driven pulley 40 that is fixed to the main shaft 38 and a driving pulley 44 that is fixed to a motor 42. Accordingly, by the actuation of the motor 42, the substrate holder 32 is allowed to rotate integrally with the main shaft 38.

Opposite to the lower surface (back surface) of the substrate W held by the substrate holder 32, there is provided a heated fluid jet pipe 48 for upwardly emitting a jet of a heated fluid, e.g. ultrapure water according to this embodiment. The heated fluid jet pipe 48 is connected to a heated fluid supply source (not shown). Further, a plating solution receiver 50 is provided which surrounds the substrate holder 32.

In operation, while rotating the substrate W which is held with its front surface facing upward by the substrate holder 32, the plating solution 34 is poured from above the substrate W to bring the plating solution 34 into contact with the upper surface (to-be-plated surface) of the substrate W, thereby forming a plated film on the upper surface of the substrate W. During the plating processing, heated ultrapure water is jetted from the heated fluid jet pipe 48 toward the back surface of the substrate W so as to heat the whole substrate uniformly with the aid of the rotation of the substrate W. By thus heating the whole substrate uniformly by heated ultrapure water and controlling the whole substrate at a constant temperature, the temperature of the substrate can be raised uniformly. This can enhance the film-forming rate and uniformity of the film thickness of the plated film over the entire surface of the substrate.

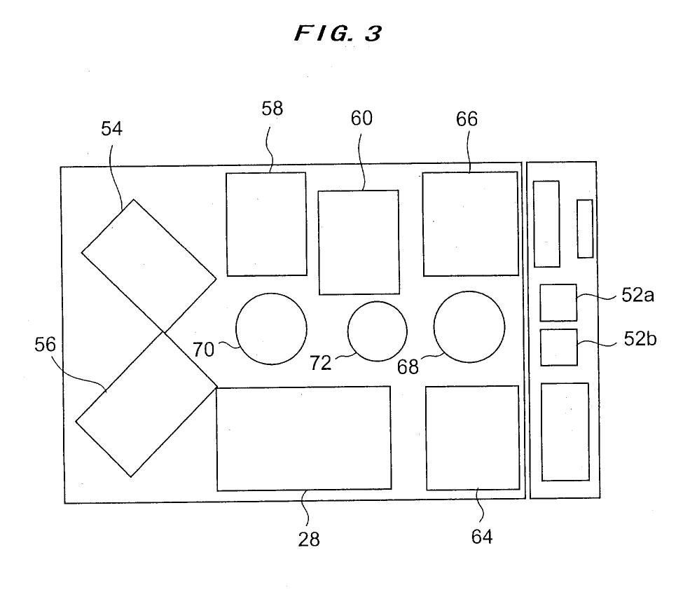

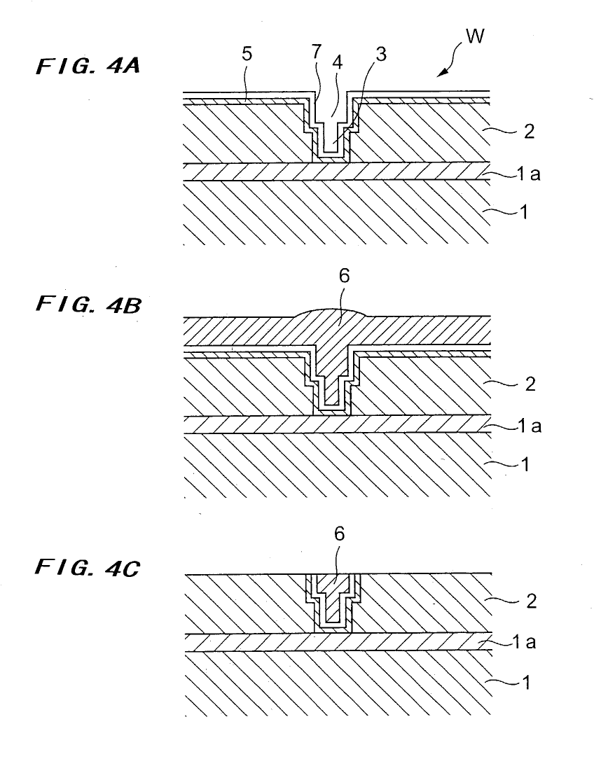

FIG. 3 shows the general construction of a substrate processing system that is provided with the electroless plating apparatus 28 shown in FIG. 2. The substrate processing system comprises loading/unloading sections 52a, 52b, cleaning apparatuses 54, 56 for carrying a pretreatment, an activation treatment apparatus 58 for carrying out an activation treatment by using a SnCl₂ solution or the like that acts as an activating agent upon plating, a catalyst-imparting treatment apparatus 60 for carrying out a catalyst-imparting treatment by using a PdCl₂ solution or the like that acts as a catalyst upon electroless plating, the electroless plating apparatus 28, cleaning/drying apparatuses 64, 66 for carrying out a post-treatment after plating treatment, two transfer devices (transfer robots) 68, 70 for transferring a substrate W between the above apparatuses, and a temporary storage stage 72.

According to this embodiment, one cleaning/drying apparatus 64 is comprised of a roll cleaning unit, and the other cleaning/drying apparatus 66 is comprised of a spin-drying unit provided with a pencil sponge. Further, the transfer device 68 positioned on the loading/unloading sections 52a, 52b side is a dry robot, and the transfer device 70 positioned on the opposite side of the temporary storage stage 72 is a wet robot provided with a reversing mechanism.

A description will now be given of a series of process steps for carrying out plating processing by the substrate processing system described above. First, a substrate W, which is held in the loading/unloading sections 52a, 52b, is taken out by one transfer device 68 and placed on the temporary storage stage 72. The other transfer device 70 transfers the substrate W to the cleaning apparatus 54 for pre-cleaning of the substrate W. After the pre-cleaning, the transfer device 70 transfers the substrate W to the activation treatment apparatus 58, where an activation treatment of the substrate W is effected using a treatment solution containing an activating agent such as SnCl₂. Thereafter, the substrate W is transferred to the adjacent catalyst-imparting treatment apparatus 60, where a catalyst-imparting treatment of the substrate W with a catalyst, such as a PdCl₂ solution, is carried out, followed by rinsing.

With respect to the above process, in the activation treatment apparatus 58, ions Sn²⁺ from the activating agent are adsorbed on the surface of the substrate W, and the ions are oxidized in the catalyst-imparting treatment apparatus 60 and become Sn⁴⁺. On the other hand, Pd²⁺ is reduced to metal Pd and precipitated on the surface of the substrate W. The precipitate acts as a catalyst layer in the next electroless plating step. The above process may also be carried out by using a one-component catalyst of Pd/Sn colloid. Though in this embodiment the catalyst-imparting treatment process is carried out in the same system by using the activation treatment apparatus 58 and the catalyst-imparting treatment apparatus 60, it is also possible to carry out the treatment independently by means of a separate apparatus and send the treated substrate W to the next step. Further, depending upon the material and conditions of the surface of recesses present in a semiconductor substrate, the activation treatment and/or the catalyst-imparting treatment may be omitted.

Next, the transfer device 70 carries the substrate W to the cleaning apparatus 56 for pre-cleaning of the substrate W. After the pre-cleaning, the transfer device 70 carries the substrate W to the electroless plating apparatus 28, where electroless plating processing of the substrate W is carried out by using a certain reducing agent and a certain plating solution. In the case of copper plating, for example, electron generated by decomposition of the reducing agent at the solid-liquid interface are imparted to Cu²⁺ via the catalyst in the surface of the substrate, and precipitated as metal Cu on the catalyst to form a plated copper film. Instead of Pd as the catalyst, other transition metals such as Fe, Co, Ni, Cu and Ag may also be employed.

Next, the transfer device 68 takes the plated substrate out of the elecctroless plating apparatus 28, and carries the substrate to the cleaning/drying apparatus 64. In the cleaning/drying apparatus 64, the substrate is water-washed by using a roll, followed by drying. The transfer device 68 then carries the substrate to the cleaning/drying apparatus 66. In the cleaning/drying apparatus 66, the substrate is subjected to finish cleaning by a pencil sponge, followed by spin-drying. Thereafter, the transfer device 68 returns the substrate to the loading/unloading sections 52a, 52b. The substrate is later sent to a CMP apparatus or an oxide film-forming apparatus.

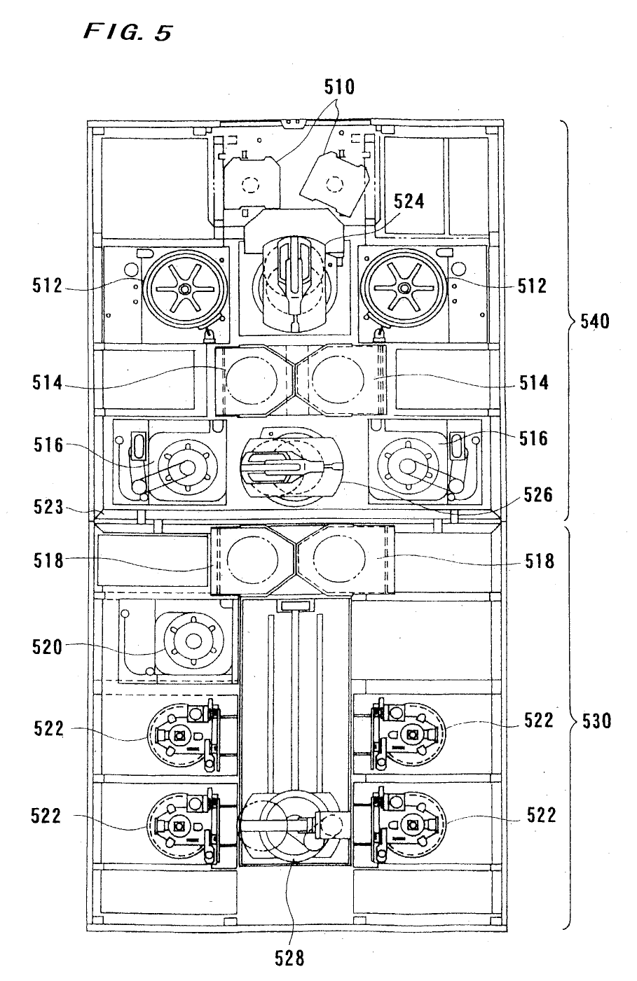

FIG. 5 shows a layout plan view of a semiconductor manufacturing apparatus provided with the edge-etching apparatus (substrate processing apparatus) described above. The semiconductor manufacturing apparatus comprises loading/unloading sections 510, each pair of cleaning/drying sections 512, first substrate stages 514, edge-etching apparatuses 516 and second substrate stages 518, a washing section 520 provided with a mechanism for reversing the substrate through 180°, and four plating sections 522. The semiconductor manufacturing apparatus is also provided with a first transferring device 524 for transferring a substrate between the loading/unloading sections 510, the cleaning/drying sections 512 and the first substrate stages 514, a second transferring device 526 for transferring a substrate between the first substrate stages 514, the edge-etching apparatuses 516 and the second substrate stages 518, and a third transferring device 528 for transferring the substrate between the second substrate stages 518, the washing section 520 and the plating sections 522.

The semiconductor manufacturing apparatus has a partition wall 523 for dividing the semiconductor manufacturing apparatus into a plating space 530 and a clean space 540. Air can individually be supplied into and exhausted from each of the plating space 530 and the clean space 540. The partition wall 523 has a shutter (not shown) capable of opening and closing. The pressure of the clean space 540 is lower than the atmospheric pressure and higher than the pressure of the plating space 530. This can prevent the air in the clean space 540 from flowing out of the plating apparatus and can prevent the air in the plating space 530 from flowing into the clean space 540.

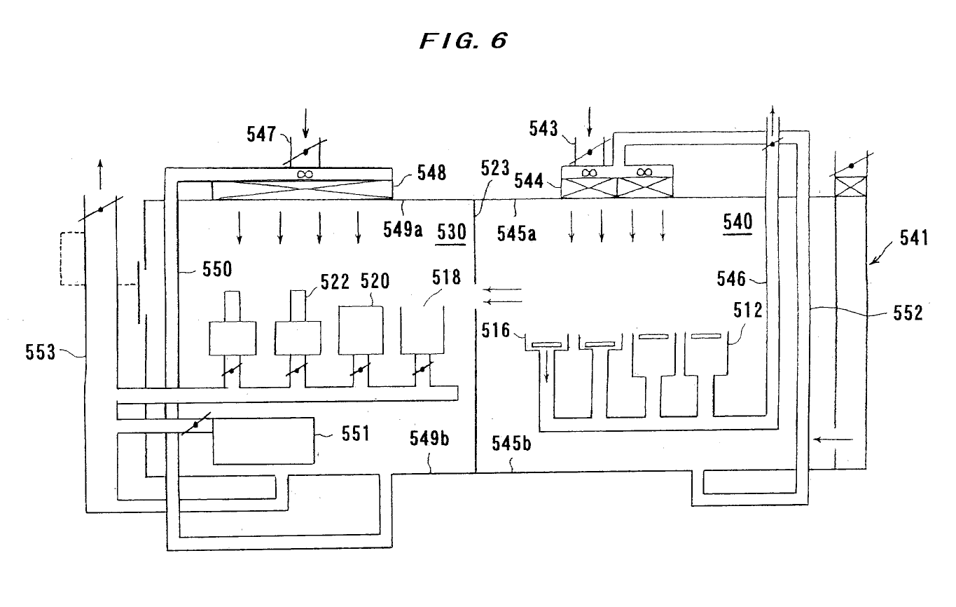

FIG. 6 is a view showing an air current in the semiconductor manufacturing apparatus. In the clean space 540, a fresh external air is introduced through a pipe 543 and pushed into the clean space 540 through a high-performance filter 544 by a fan. Hence, a down-flow clean air is supplied from a ceiling 545a to positions around the cleaning/drying sections 512 and the edge-etching apparatuses 516. A large part of the supplied clean air is returned from a floor 545b through a circulation pipe 552 to the ceiling 545a, and pushed again into the clean space 540 through the high-performance filter 544 by the fan, to thus circulate in the clean space 540. A part of the air is discharged from the cleaning/drying sections 512 and the edge-etching apparatuses 516 through a pipe 546 to the exterior, so that the pressure of the clean space 540 is set to be lower than the atmospheric pressure.

The plating space 530 having the washing section 520 and the plating sections 522 therein is not a clean space (but a contamination zone). However, it is not acceptable to attach particles to the surface of the substrate. Therefore, in the plating space 530, a fresh external air is introduced through a pipe 547, and a down-flow clean air is pushed into the plating space 530 through a high-performance filter 548 by a fan from a ceiling 549a side, for thereby preventing particles from being attached to the surface of the substrate. However, if the whole flow rate of the down-flow clean air is supplied by only an external air supply and exhaust, then enormous air supply and exhaust are required. Therefore, the air is discharged through a pipe 553 to the exterior, and a large part of the down-flow is supplied by a circulating air through a circulation pipe 550 extended from a floor 549b, in such a state that the pressure of the plating space 530 is maintained to be lower than the pressure of the clean space 540.

Thus, the air returned to the ceiling 549a through the circulation pipe 550 is pushed again into the plating space 530 through the high-performance filter 548 by the fan. Hence, a clean air is supplied into the plating space 530 to thus circulate in the plating space 530. In this case, air containing chemical mist or gas emitted from the washing section 520, the plating sections 522, the transferring device 528, and a plating solution regulating bath 551 is discharged through the pipe 553 to the exterior. Thus, the pressure of the plating space 530 is controlled so as to be lower than the pressure of the clean space 540.

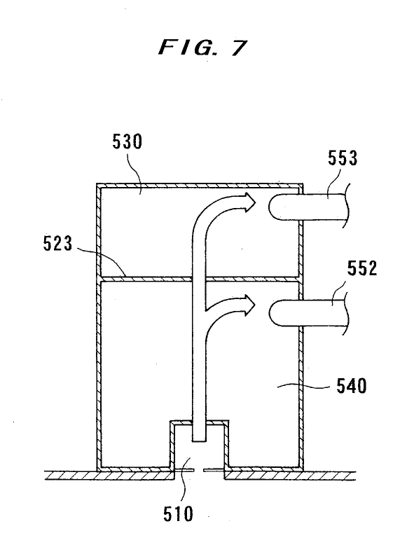

When the shutters (not shown) are opened, therefore, air flows successively through the loading/unloading sections 510, the clean space 540, and the plating space 530, as shown in FIG. 6. Air discharged from the clean space 540 and the plating space 530 flows through the ducts 552, 553 into a common duct 554, as shown in FIG. 7.

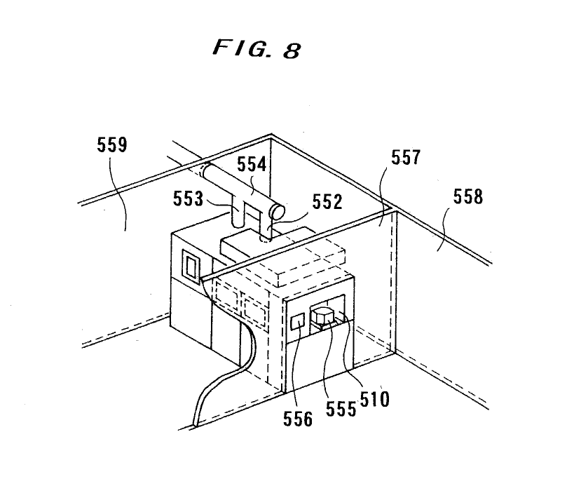

FIG. 8 is an outline view showing an example of the semiconductor manufacturing apparatus, which is placed in the clean room. The loading/unloading sections 510 includes a side wall which has a cassette transfer port 555 defined therein and a control panel 556, and which is exposed to a working zone 558 that is compartmented in the clean room by a partition wall 557. Other sidewalls of the semiconductor manufacturing apparatus are housed in the utility zone 559 whose air cleanness is lower than the air cleanness in the working zone 558.

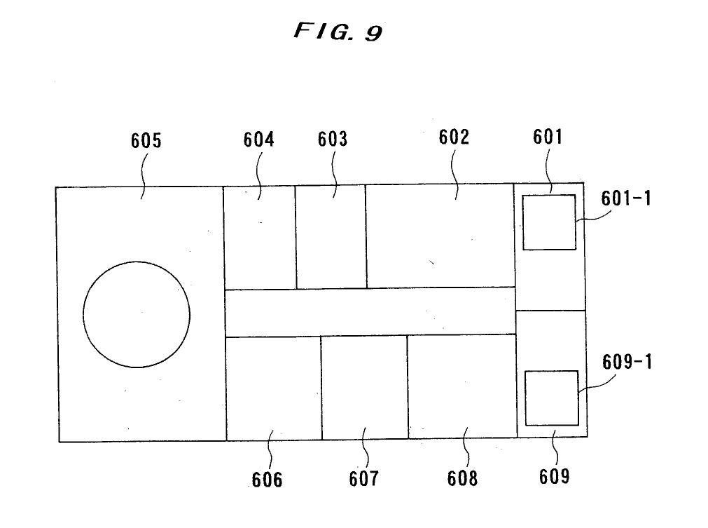

FIG. 9 is a view showing the plan construction of another semiconductor manufacturing apparatus. As shown in FIG. 9, the semiconductor manufacturing apparatus comprises a loading unit 601 for loading a semiconductor substrate, a copper plating chamber 602 for plating a semiconductor substrate with copper, a pair of water cleaning chambers 603, 604 for cleaning a semiconductor substrate with water, a CMP unit 605 for chemical mechanical polishing (CMP) a semiconductor substrate, a pair of water cleaning chambers 606, 607, a drying chamber 608, and an unloading unit 609 for unloading a semiconductor substrate with an interconnection film thereon. A substrate transfer mechanism (not shown) is provided as a device for transferring the substrate between these components. Thus, the semiconductor manufacturing apparatus for manufacturing a semiconductor substrate with an interconnection is composed.

The semiconductor manufacturing apparatus operates as follows: The substrate transfer mechanism transfers a semiconductor substrate W on which an interconnection film has not yet been formed from a substrate cassette 601-1 placed in the loading unit 601 to the copper plating chamber 602. In the copper plating chamber 602, a plated copper film is formed on a surface of the semiconductor substrate W having an interconnection region composed of interconnection trenches and interconnection holes (contact holes).

After the plated copper film is formed on the semiconductor substrate W in the copper plating chamber 602, the semiconductor substrate W is transferred to the water cleaning chambers 603, 604 by the substrate transfer mechanism and cleaned by water. The cleaned semiconductor substrate W is transferred to the CMP unit 605 by the substrate transfer mechanism. The CMP unit 605 removes the unwanted plated copper film from the surface of the semiconductor substrate W, leaving a portion of the plated copper film in the interconnection trenches and the interconnection holes.

Then, the semiconductor substrate W with the remaining plated copper film is transferred to the water cleaning chambers 606, 607 by the substrate transfer mechanism and cleaned by water. The cleaned semiconductor substrate W is then dried in the drying chamber 608, after which the dried semiconductor substrate W with the remaining plated copper film serving as an interconnection film is placed into a substrate cassette 609-1 in the unloading unit 609.

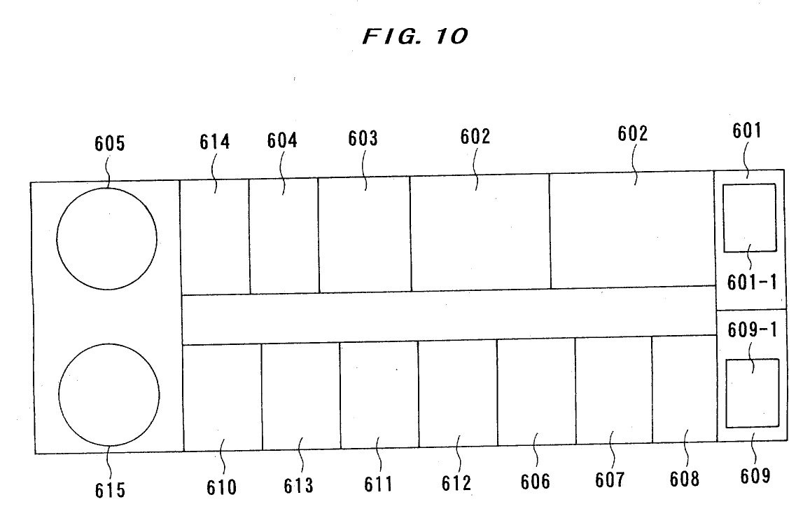

FIG. 10 is a view showing the plan constitution of another semiconductor manufacturing apparatus for manufacturing a semiconductor substrate with an interconnection. The semiconductor manufacturing apparatus shown in FIG. 10 differs from the apparatus shown in FIG. 5 in that it additionally includes a copper plating chamber 602, a water cleaning chamber 610, a pretreatment chamber 611, a cap plating chamber 612 for forming a protective plated layer on a plated copper film, a CMP unit 615, and water cleaning chambers 613, 614. These components are combined into a single unitary arrangement as an apparatus.

The semiconductor manufacturing apparatus as follows: A plated copper film is formed on a surface of the semiconductor substrate which has an interconnection region composed of interconnection trenches and interconnection holes. Then, in the CPM unit 605, the plated copper film is removed from the surface of the semiconductor substrate W, leaving a portion of the plated copper film in the interconnection trenches and the interconnection holes.

Thereafter, the semiconductor substrate W with the remaining plated copper film is transferred to the water cleaning chamber 610, in which the semiconductor substrate W is cleaned with water. Then, the semiconductor substrate W is pretreated in the pretreatment chamber 611 for the cap plating described bellow. The pretreated semiconductor substrate W is transferred to the cap plating chamber 612. In the cap plating chamber 612, a protective plated layer is formed on the plated copper film in the interconnection region on the semiconductor substrate W. For example, the protective plated layer is formed with a Ni—B alloy in the electroless plating bath. The semiconductor substrate W formed the protective plated layer is cleaned by water in the water cleaning chambers 606, 607, and then dried in the drying chamber 608.

After an upper portion of the protective plated layer deposited on the plated copper film is polished off to planarize the protective plated layer in the CMP unit 615, the semiconductor substrate W is cleaned by water in the water cleaning chambers 613, 614, dried in the drying chamber 608, and then transferred to the substrate cassette 609-1 in the unloading unit 609.

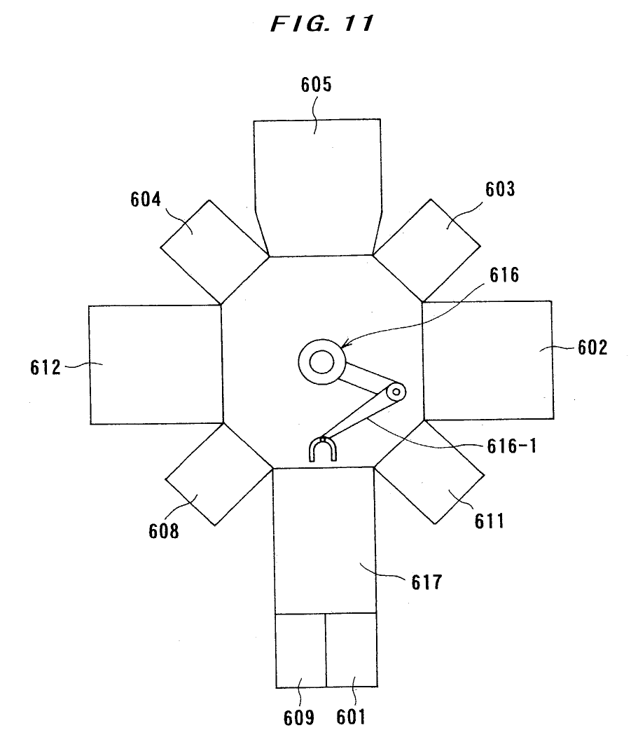

FIG. 11 is a view showing the plan constitution of another semiconductor manufacturing apparatus for manufacturing a semiconductor substrate with an interconnection. As shown in FIG. 11, the semiconductor manufacturing apparatus includes a robot 616 at its center which has a robot arm 616-1, and also has a copper plating chamber 602 for plating with copper, a water cleaning chamber 603, a water cleaning chamber 604, a CMP unit 605, a cap plating chamber 612, a drying chamber 608, and a loading/unloading section 617 which are disposed around the robot 616 and positioned within the reach of the robot arm 616-1. A loading unit 601 for loading semiconductor substrates and an unloading unit 609 for unloading semiconductor substrates is disposed adjacent to the loading/unloading section 617.

The semiconductor manufacturing apparatus for manufacturing a semiconductor substrate with an interconnection substrate operates as follows: A semiconductor substrate to be plated is transferred from the loading unit 601 to the loading/unloading section 617, from which the semiconductor substrate is received by the robot arm 616-1 and transferred thereby to the copper plating chamber 602. In the copper plating chamber 602, a plated copper film is formed on a surface of the semiconductor substrate which has an interconnection region composed of interconnection trenches and interconnection holes. The semiconductor substrate with the plated copper film formed thereon is transferred by the robot arm 616-1 to the CMP unit 605. In the CMP unit 605, the plated copper film is removed from the surface of the semiconductor substrate W, leaving a portion of the plated copper film in the interconnection trenches and the interconnection holes.

The semiconductor substrate is then transferred by the robot arm 616-1 to the water cleaning chamber 604, in which the semiconductor substrate is cleaned by water. Thereafter, the semiconductor substrate is transferred to the pretreatment chamber 611, in which the semiconductor substrate is pretreated therein for the cap plating. The pretreated semiconductor substrate is transferred by the robot arm 616-1 to the cap plating chamber 612. In the cap plating chamber 612, a protective plated layer is formed on the plated copper film in the interconnection region composed of interconnection trenches and interconnection holes on the semiconductor substrate W. The semiconductor substrate with the protective plated layer formed thereon is transferred by the robot arm 616-1 to the water cleaning chamber 604, in which the semiconductor substrate is cleaned by water. The cleaned semiconductor substrate is transferred to the drying chamber 608, in which the semiconductor substrate is dried. The dried semiconductor substrate is transferred to the loading/unloading section 617, from which the plated semiconductor substrate is transferred to the unloading unit 609.

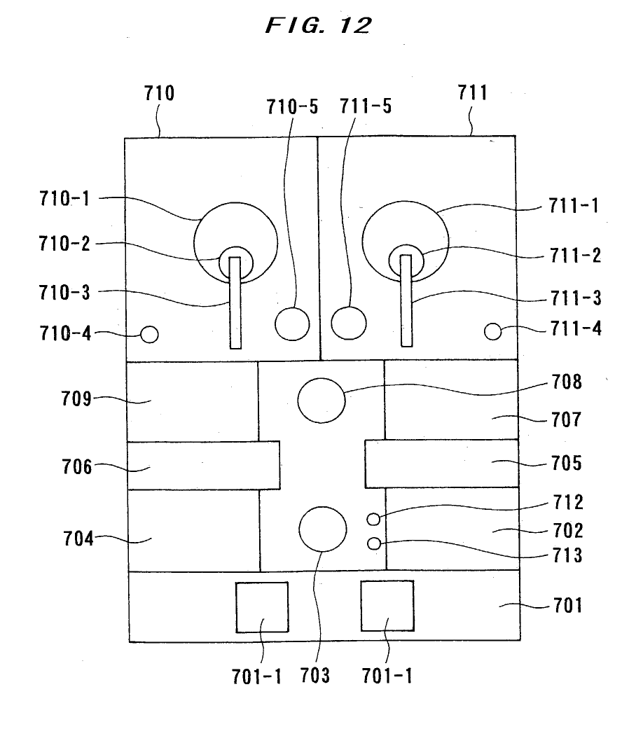

FIG. 12 is a view showing the plan constitution of another semiconductor manufacturing apparatus. The s semiconductor manufacturing is of a constitution in which there are provided a loading/unloading section 701, a copper plating unit 702, a first robot 703, a third cleaning machine 704, a reversing machine 705, a reversing machine 706, a second cleaning machine 707, a second robot 708, a first cleaning machine 709, a first polishing apparatus 710, and a second polishing apparatus 711. A before-plating and after-plating film thickness measuring instrument 712 for measuring the film thickness before and after plating, and a dry state film thickness measuring instrument 713 for measuring the film thickness of a semiconductor substrate W in a dry state after polishing are placed near the first robot 703.

The first polishing apparatus (polishing unit) 710 has a polishing table 710-1, a top ring 710-2, a top ring head 710-3, a film thickness measuring instrument 710-4, and a pusher 710-5. The second polishing apparatus (polishing unit) 711 has a polishing table 711-1, a top ring 711-2, a top ring head 711-3, a film thickness measuring instrument 711-4, and a pusher 711-5.

A cassette 701-1 accommodating the semiconductor substrates W, in which via holes and trenches for interconnect are formed, and a seed layer is formed thereon is placed on a loading port of the loading/unloading section 701. The first robot 703 takes out the semiconductor substrate W from the cassette 701-1, and carries the semiconductor substrate W into the copper plating unit 702 where a plated copper film is formed. At this time, the film thickness of the seed layer is measured with the before-plating and after-plating film thickness measuring instrument 712. The plated copper film is formed by carrying out hydrophilic treatment of the surface of the semiconductor substrate W, and then copper plating. After formation of the plated copper film, rinsing or cleaning of the semiconductor substrate W is carried out in the copper plating unit 702. In case of having extra time, the substrate may be dried.

When the semiconductor substrate W is taken out from the copper plating unit 702 by the first robot 703, the film thickness of the plated copper film is measured with the before-plating and after-plating film thickness measuring instrument 712. The results of its measurement are recorded into a recording device (not shown) as record data on the semiconductor substrate, and are used for judgment of an abnormality of the copper plating unit 702. After measurement of the film thickness, the first robot 703 transfers the semiconductor substrate W to the reversing machine 705, and the reversing machine 705 reverses the semiconductor substrate W (the surface on which the plated copper film has been formed faces downward). The first polishing apparatus 710 and the second polishing apparatus 711 perform polishing in a serial mode and a parallel mode. Next, polishing in the serial mode will be described.

In the serial mode polishing, a primary polishing is performed by the polishing apparatus 710, and a secondary polishing is performed by the polishing apparatus 711. The second robot 708 picks up the semiconductor substrate W on the reversing machine 705, and places the semiconductor substrate W on the pusher 710-5 of the polishing apparatus 710. The top ring 710-2 attracts the semiconductor substrate W on the pusher 710-5 by suction, and brings the surface of the plated copper film of the semiconductor substrate W into contact with a polishing surface of the polishing table 710-1 under pressure to perform a primary polishing. With the primary polishing, the plated copper film is basically polished. The polishing surface of the polishing table 710-1 is composed of foamed polyurethane such as IC1000, or a material having abrasive grains fixed thereto or impregnated therein. Upon relative movements of the polishing surface and the semiconductor substrate W, the plated copper film is polished.

After completion of polishing of the plated copper film, the semiconductor substrate W is returned onto the pusher 710-5 by the top ring 710-2. The second robot 708 picks up the semiconductor substrate W, and introduces it into the first cleaning machine 709. At this time, a chemical liquid may be ejected toward the face and backside of the semiconductor substrate W on the pusher 710-5 to remove particles therefrom or cause particles to be difficult to adhere thereto.

After completion of cleaning in the first cleaning machine 709, the second robot 708 picks up the semiconductor substrate W, and places the semiconductor substrate W on the pusher 711-5 of the second polishing apparatus 711. The top ring 711-2 attracts the semiconductor substrate W on the pusher 711-5 by suction, and brings the surface of the semiconductor substrate W, which has the barrier layer formed thereon, into contact with a polishing surface of the polishing table 711-1 under pressure to perform the secondary polishing. With this secondary polishing, the barrier layer is polished. However, there may be a case in which a copper film and an oxide film left after the primary polishing are also polished.

A polishing surface of the polishing table 711-1 is composed of foamed polyurethane such as IC1000, or a material having abrasive grains fixed thereto or impregnated therein. Upon relative movements of the polishing surface and the semiconductor substrate W, polishing is carried out. At this time, silica, alumina, ceria, or the like is used as abrasive grains or slurry. A chemical liquid is adjusted depending on the type of the film to be polished.

Detection of an end point of the secondary polishing is performed by measuring the film thickness of the barrier layer mainly with the use of the optical film thickness measuring instrument, and detecting the film thickness which has become zero, or the surface of an insulating film comprising SiO₂ shows up. Furthermore, a film thickness measuring instrument with an image processing function is used as the film thickness measuring instrument 711-4 provided near the polishing table 711-1. By use of this measuring instrument, measurement of the oxide film is made, the results are stored as processing records of the semiconductor substrate W, and used for judging whether the semiconductor substrate W in which secondary polishing has been finished can be transferred to a subsequent step or not. If the endpoint of the secondary polishing is not reached, re-polishing is performed. If over-polishing has been performed beyond a prescribed value due to any abnormality, then the semiconductor manufacturing apparatus is stopped to avoid next polishing so that defective products will not increase.

After completion of the secondary polishing, the semiconductor substrate W is moved to the pusher 711-5 by the top ring 711-2. The second robot 708 picks up the semiconductor substrate W on the pusher 711-5. At this time, a chemical liquid may be ejected toward the face and backside of the semiconductor substrate W on the pusher 711-5 to remove particles therefrom or cause particles to be difficult to adhere thereto.

The second robot 708 carries the semiconductor substrate W into the second cleaning machine 707 where cleaning of the semiconductor substrate W is performed. The constitution of the second cleaning machine 707 is also the same as the constitution of the first cleaning machine 709. The face of the semiconductor substrate W is scrubbed with the PVA sponge rolls using a cleaning liquid comprising pure water to which a surface active agent, a chelating agent, or a pH regulating agent is added. A strong chemical liquid such as DHF is ejected from a nozzle toward the backside of the semiconductor substrate W to perform etching of the diffused copper thereon. If there is no problem of diffusion, scrubbing cleaning is performed with the PVA sponge rolls using the same chemical liquid as that used for the face.

After completion of the above cleaning, the second robot 708 picks up the semiconductor substrate W and transfers it to the reversing machine 706, and the reversing machine 706 reverses the semiconductor substrate W. The semiconductor substrate W which has been reversed is picked up by the first robot 703, and transferred to the third cleaning machine 704. In the third cleaning machine 704, megasonic water excited by ultrasonic vibrations is ejected toward the face of the semiconductor substrate W to clean the semiconductor substrate W. At this time, the face of the semiconductor substrate W may be cleaned with a known pencil type sponge using a cleaning liquid comprising pure water to which a surface active agent, a chelating agent, or a pH regulating agent is added. Thereafter, the semiconductor substrate W is dried by spin-drying.

As described above, if the film thickness has been measured with the film thickness measuring instrument 711-4 provided near the polishing table 711-1, then the semiconductor substrate W is accommodated into the cassette placed on the unloading port of the loading/unloading section 701.

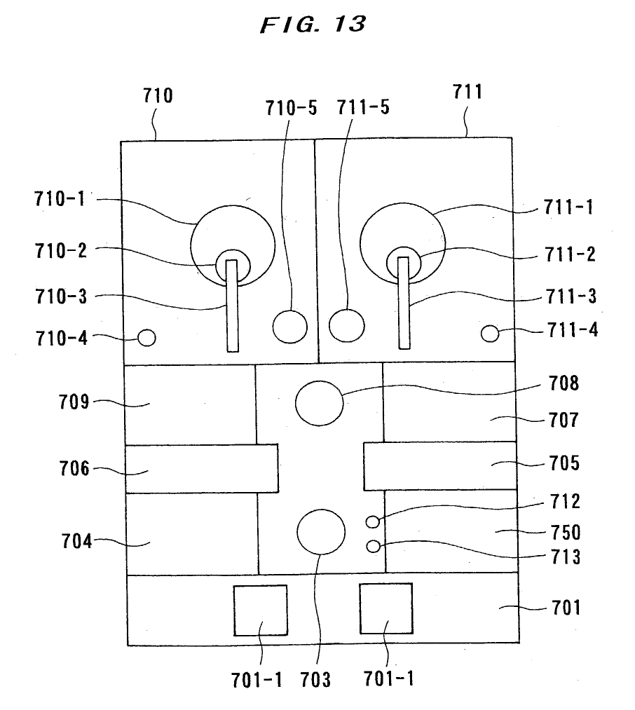

FIG. 13 is a view showing the plan constitution of another semiconductor manufacturing apparatus. The semiconductor manufacturing apparatus differs from the semiconductor manufacturing apparatus shown in FIG. 12 in that a cap plating unit 750 is provided instead of the copper plating unit 702 in FIG. 12.

A cassette 701-1 accommodating the semiconductor substrates W formed plated copper film is placed on a loading/unloading section 701. The semiconductor substrate W taken out from the cassette 701-1 is transferred to the first polishing apparatus 710 or second polishing apparatus 711 in which the surface of the plated copper film is polished. After completion of polishing of the plated copper film, the semiconductor substrate W is transferred to the first cleaning machine 709 and cleaned in the first cleaning machine 709.

After completion of cleaning in the first cleaning machine 709, the semiconductor substrate W is transferred to the cap plating unit 750 where cap plating is applied onto the surface of the plated copper film with the aim of preventing oxidation of plated copper film due to the atmosphere. The semiconductor substrate to which cap plating has been applied is carried by the second robot 708 from the cap plating unit 750 to the second cleaning machine 707 where it is cleaned with pure water or deionized water. The semiconductor substrate after completion of cleaning is returned into the cassette 701-1 placed on the loading/unloading section 701.

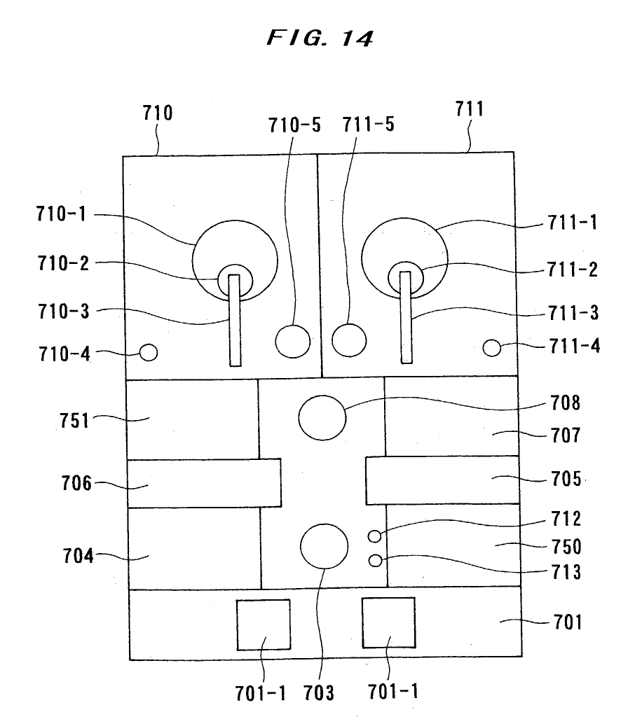

FIG. 14 is a view showing the plan constitution of still another semiconductor manufacturing apparatus. The semiconductor manufacturing apparatus differs from the semiconductor manufacturing apparatus shown in FIG. 13 in that an annealing unit 751 is provided instead of the first cleaning machine 709 in FIG. 13.

The semiconductor substrate W, which is polished in the first polishing unit 710 or the second polishing unit 711, and cleaned in the second cleaning machine 707 described above, is transferred to the cap plating unit 750 where cap plating is applied onto the surface of the plated copper film. The semiconductor substrate W to which cap plating has been applied is carried by the first robot 703 from the cap plating unit 750 to the third cleaning machine 704 where it is cleaned.

After completion of cleaning in the first cleaning machine 709, the semiconductor substrate W is transferred to the annealing unit 751 in which the substrate is annealed, whereby the plated copper film is alloyed so as to increase the electromigration resistance of the plated copper film. The semiconductor substrate W to which annealing treatment has been applied is carried from the annealing unit 751 to the second cleaning machine 707 where it is cleaned with pure water or deionized water. The semiconductor substrate W after completion of cleaning is returned into the cassette 701-1 placed on the loading/unloading section 701.

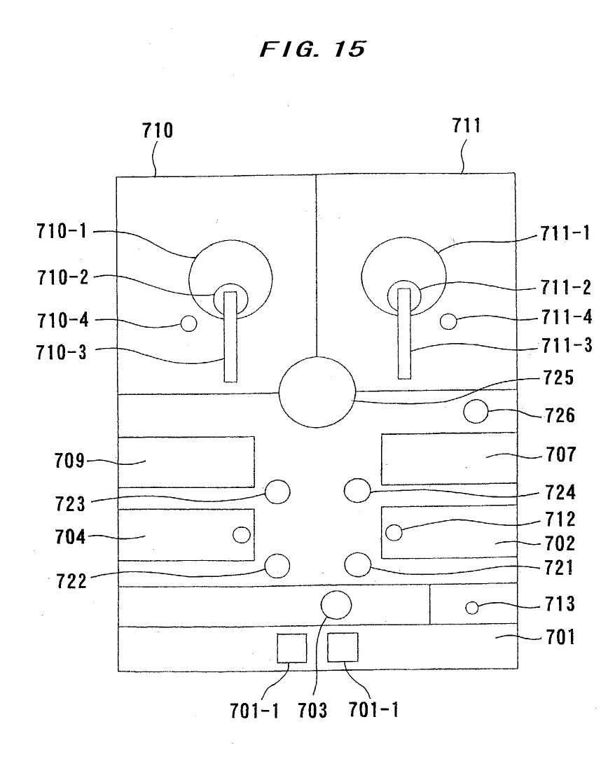

FIG. 15 is a view showing the plan constitution of another semiconductor manufacturing apparatus. In FIG. 15, portions denoted by the same reference numerals as those in FIG. 12 show the same or corresponding portions. In the semiconductor manufacturing apparatus, a pusher indexer 725 is disposed close to a first polishing apparatus 710 and a second polishing apparatus 711. Substrate placing tables 721, 722 are disposed close to a third cleaning machine 704 and a copper plating unit 702, respectively. A robot 723 is disposed close to a first cleaning machine 709 and the third cleaning machine 704. Further, a robot 724 is disposed close to a second cleaning machine 707 and the copper plating unit 702, and a dry state film thickness measuring instrument 713 is disposed close to a loading/unloading section 701 and a first robot 703.

In the semiconductor manufacturing apparatus of the above constitution, the first robot 703 takes out a semiconductor substrate W from a cassette 701-1 placed on the load port of the loading/unloading section 701. After the film thickness of a barrier layer and a seed layer are measured with the dry state film thickness measuring instrument 713, the first robot 703 places the semiconductor substrate W on the substrate placing table 721. In the case where the dry state film thickness measuring instrument 713 is provided on the hand of the first robot 703, the film thickness is measured thereon, and the substrate is placed on the substrate placing table 721. The second robot 723 transfers the semiconductor substrate W on the substrate placing table 721 to the copper plating unit 702 in which a plated copper film is formed. After formation of the plated copper film, the film thickness of the plated copper film is measured with a before-plating and after-plating film thickness measuring instrument 712. Then, the second robot 723 transfers the semiconductor substrate W to the pusher indexer 725 and loads it thereon.

[Serial Mode]

In the serial mode, a top ring 710-2 holds the semiconductor substrate W on the pusher indexer 725 by suction, transfers it to a polishing table 710-1, and presses the semiconductor substrate W against a polishing surface on the polishing table 710-1 to perform polishing. Detection of the end point of polishing is performed by the same method as described above. The semiconductor substrate W after completion of polishing is transferred to the pusher indexer 725 by the top ring 710-2, and loaded thereon. The second robot 723 takes out the semiconductor substrate W, and carries it into the first cleaning machine 709 for cleaning. Then, the semiconductor substrate W is transferred to the pusher indexer 725, and loaded thereon.

A top ring 711-2 holds the semiconductor substrate W on the pusher indexer 725 by suction, transfers it to a polishing table 711-1, and presses the semiconductor substrate W against a polishing surface on the polishing table 711-1 to perform polishing. Detection of the end point of polishing is performed by the same method as described above. The semiconductor substrate W after completion of polishing is transferred to the pusher indexer 725 by the top ring 711-2, and loaded thereon. The third robot 724 picks up the semiconductor substrate W, and its film thickness is measured with a film thickness measuring instrument 726. Then, the semiconductor substrate W is carried into the second cleaning machine 707 for cleaning. Thereafter, the semiconductor substrate W is carried into the third cleaning machine 704, where it is cleaned and then dried by spin-drying. Then, the semiconductor substrate W is picked up by the third robot 724, and placed on the substrate placing table 722.

[Parallel Mode]

In the parallel mode, the top ring 710-2 or 711-2 holds the semiconductor substrate W on the pusher indexer 725 by suction, transfers it to the polishing table 710-1 or 711-1, and presses the semiconductor substrate W against the polishing surface on the polishing table 710-1 or 711-1 to perform polishing. After measurement of the film thickness, the third robot 724 picks up the semiconductor substrate W, and places it on the substrate placing table 722.

The first robot 703 transfers the semiconductor substrate W on the substrate placing table 722 to the dry state film thickness measuring instrument 713. After the film thickness is measured, the semiconductor substrate W is returned to the cassette 701-1 of the loading/unloading section 701.

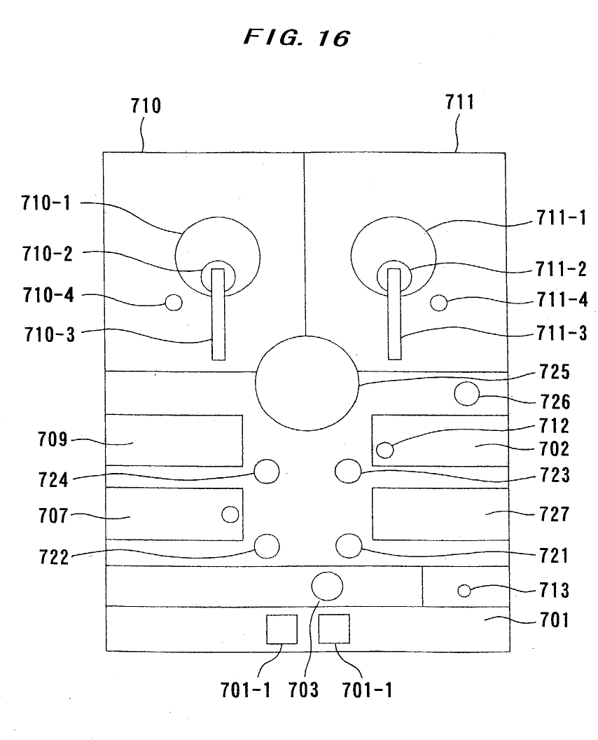

FIG. 16 is a view showing the plan constitution of another semiconductor manufacturing apparatus. The semiconductor manufacturing apparatus is such a semiconductor manufacturing apparatus which forms a seed layer and a plated copper film on a semiconductor substrate W having no seed layer formed thereon, and polishes these films to form interconnects.

In the semiconductor manufacturing apparatus, a pusher indexer 725 is disposed close to a first polishing apparatus 710 and a second polishing apparatus 711, substrate placing tables 721, 722 are disposed close to a second cleaning machine 707 and a seed layer forming unit 727, respectively, and a robot 723 is disposed close to the seed layer forming unit 727 and a copper plating unit 702. Further, a robot 724 is disposed close to a first cleaning machine 709 and the second cleaning machine 707, and a dry state film thickness measuring instrument 713 is disposed close to a loading/unloading section 701 and a first robot 703.

The first robot 703 takes out a semiconductor substrate W having a barrier layer thereon from a cassette 701-1 placed on the load port of the loading/unloading section 701, and places it on the substrate placing table 721. Then, the second robot 723 transfers the semiconductor substrate W to the seed layer forming unit 727 where a seed layer is formed. The seed layer is formed by electroless plating. The second robot 723 enables the semiconductor substrate having the seed layer formed thereon to be measured in thickness of the seed layer by the before-plating and after-plating film thickness measuring instrument 712. After measurement of the film thickness, the semiconductor substrate is carried into the copper plating unit 702 where a plated copper film is formed.

After formation of the plated copper film, its film thickness is measured, and the semiconductor substrate is transferred to a pusher indexer 725. A top ring 710-2 or 711-2 holds the semiconductor substrate W on the pusher indexer 725 by suction, and transfers it to a polishing table 710-1 or 711-1 to perform polishing. After polishing, the top ring 710-2 or 711-2 transfers the semiconductor substrate W to a film thickness measuring instrument 710-4 or 711-4 to measure the film thickness. Then, the top ring 710-2 or 711-2 transfers the semiconductor substrate W to the pusher indexer 725, and places it thereon.

Then, the third robot 724 picks up the semiconductor substrate W from the pusher indexer 725, and carries it into the first cleaning machine 709. The third robot 724 picks up the cleaned semiconductor substrate W from the first cleaning machine 709, carries it into the second cleaning machine 707, and places the cleaned and dried semiconductor substrate on the substrate placing table 722. Then, the first robot 703 picks up the semiconductor substrate W, and transfers it to the dry state film thickness measuring instrument 713 in which the film thickness is measured, and the first robot 703 carries it into the cassette 701-1 placed on the unload port of the loading/unloading section 701.

In the semiconductor manufacturing apparatus shown in FIG. 16, interconnects are formed by forming a barrier layer, a seed layer and a plated copper film on a semiconductor substrate W having via holes or trenches of a circuit pattern formed therein, and polishing them.

The cassette 701-1 accommodating the semiconductor substrates W before formation of the barrier layer is placed on the load port of the loading/unloading section 701. The first robot 703 takes out the semiconductor substrate W from the cassette 701-1 placed on the load port of the loading/unloading section 701, and places it on the substrate placing table 721. Then, the second robot 723 transfers the semiconductor substrate W to the seed layer forming unit 727 where a barrier layer and a seed layer are formed. The barrier layer and the seed layer are formed by electroless plating. The second robot 723 brings the semiconductor substrate W having the barrier layer and the seed layer formed thereon to the before-plating and after-plating film thickness measuring instrument 712 which measures the film thickness of the barrier layer and the seed layer. After measurement of the film thickness, the semiconductor substrate W is carried into the copper plating unit 702 where a plated copper film is formed.

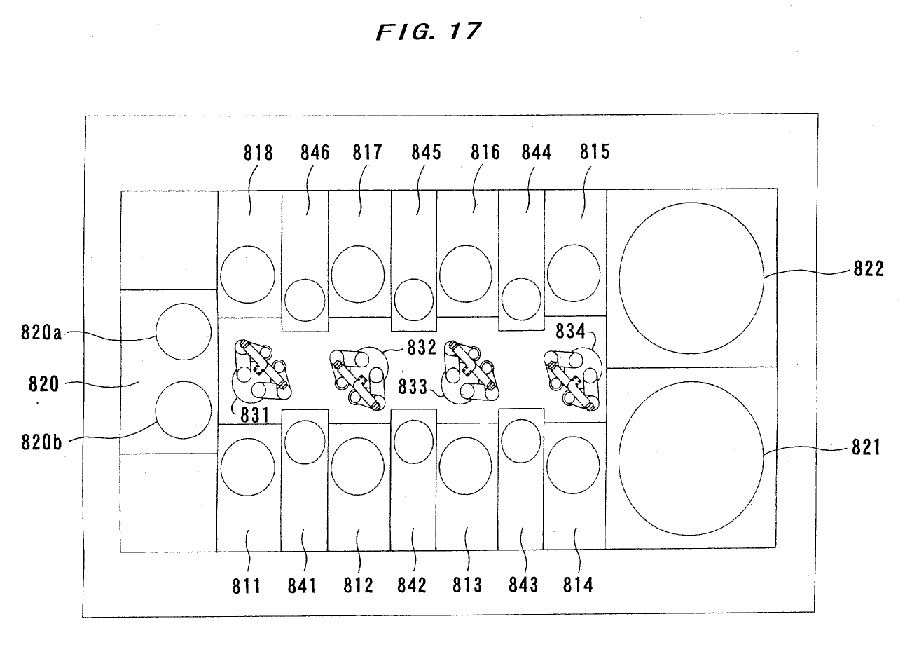

FIG. 17 is a view showing the plan constitution of another semiconductor manufacturing apparatus. In the semiconductor manufacturing apparatus, there are provided a barrier layer forming unit 811, a seed layer forming unit 812, a plating unit 813, an annealing unit 814, a first cleaning unit 815, a bevel and backside cleaning unit (bevel etching apparatus) 816, a cap plating unit 817, a second cleaning unit 818, a first aligner and film thickness measuring instrument 841, a second aligner and film thickness measuring instrument 842, a first substrate reversing machine 843, a second substrate reversing machine 844, a substrate temporary placing table 845, a third film thickness measuring instrument 846, a loading/unloading section 820, a first polishing apparatus 821, a second polishing apparatus 822, a first robot 831, a second robot 832, a third robot 833, and a fourth robot 834. The film thickness measuring instruments 841, 842, and 846 are units, have the same size as the frontage dimension of other units (plating, cleaning, annealing units, and the like), and are thus interchangeable.

In this example, an electroless Ni—B plating apparatus can be used as the barrier layer forming unit 811, an electroless copper plating apparatus can be used as the seed layer forming unit 812, and an electroplating apparatus can be used as the plating unit 813.

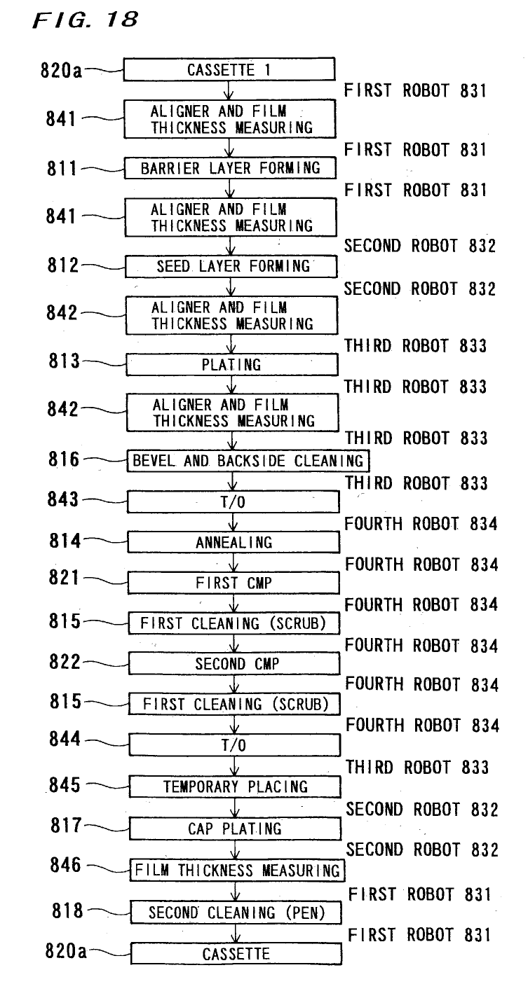

FIG. 18 is a flow chart showing the flow of the respective steps in the present semiconductor manufacturing apparatus. The respective steps in the apparatus will be described according to this flow chart. First, a semiconductor substrate taken out by the first robot 831 from a cassette 820a placed on the load and unload section 820 is placed in the first aligner and film thickness measuring instrument 841, in such a state that its surface, to be plated, faces upward. In order to set a reference point for a position at which film thickness measurement is made, notch alignment for film thickness measurement is performed, and then film thickness data on the semiconductor substrate before formation of a copper film are obtained.

Then, the semiconductor substrate is transferred to the barrier layer forming unit 811 by the first robot 831. The barrier layer forming unit 811 is such an apparatus for forming a barrier layer on the semiconductor substrate by electroless Ni—B plating, and the barrier layer forming unit 811 forms a Ni—B film as a film for preventing copper from diffusing into an interlayer insulator film (e.g. SiO₂) of a semiconductor device. The semiconductor substrate discharged after cleaning and drying steps is transferred by the first robot 831 to the first aligner and film thickness measuring instrument 841, where the film thickness of the semiconductor substrate, i.e., the film thickness of the barrier layer is measured.

The semiconductor substrate after film thickness measurement is carried into the seed layer forming unit 812 by the second robot 832, and a seed layer is formed on the barrier layer by electroless copper plating. The semiconductor substrate discharged after cleaning and drying steps is transferred by the second robot 832 to the second aligner and film thickness measuring instrument 842 for determination of a notch position, before the semiconductor substrate is transferred to the plating unit 813, which is an impregnation plating unit, and then notch alignment for copper plating is performed by the film thickness measuring instrument 842. If necessary, the film thickness of the semiconductor substrate before formation of a copper film may be measured again in the film thickness measuring instrument 842.

The semiconductor substrate which has completed notch alignment is transferred by the third robot 833 to the plating unit 813 where copper plating is applied to the semiconductor substrate. The semiconductor substrate discharged after cleaning and drying steps is transferred by the third robot 833 to the bevel and backside cleaning unit 816 where an unnecessary copper film (seed layer) at a peripheral portion of the semiconductor substrate is removed. In the bevel and backside cleaning unit 816, the bevel is etched in a preset time, and copper adhering to the backside of the semiconductor substrate is cleaned with a chemical liquid such as hydrofluoric acid. At this time, before transferring the semiconductor substrate to the bevel and backside cleaning unit 816, film thickness measurement of the semiconductor substrate may be made by the second aligner and film thickness measuring instrument 842 to obtain the thickness value of the copper film formed by plating, and based on the obtained results, the bevel etching time may be changed arbitrarily to carry out etching. The region etched by bevel etching is a region which corresponds to a peripheral edge portion of the substrate and has no circuit formed therein, or a region which is not utilized finally as a chip although a circuit is formed. A bevel portion is included in this region.

The semiconductor substrate discharged after cleaning and drying steps in the bevel and backside cleaning unit 816 is transferred by the third robot 833 to the substrate reversing machine 843. After the semiconductor substrate is turned over by the substrate reversing machine 843 to cause the plated surface to be faced downward, the semiconductor substrate is introduced into the annealing unit 814 by the fourth robot 834 for thereby stabilizing an interconnection portion. Before and/or after annealing treatment, the semiconductor substrate is carried into the second aligner and film thickness measuring instrument 842 where the film thickness of a copper film formed on the semiconductor substrate is measured. Then, the semiconductor substrate is carried by the fourth robot 834 into the first polishing apparatus 821 in which the copper film and the seed layer of the semiconductor substrate are polished.

At this time, desired abrasive grains or the like are used, but fixed abrasive may be used in order to prevent dishing and enhance flatness of the surface. After completion of primary polishing, the semiconductor substrate is transferred by the fourth robot 834 to the first cleaning unit 815 where it is cleaned. This cleaning is scrub-cleaning in which rolls having substantially the same length as the diameter of the semiconductor substrate are placed on the surface and the backside of the semiconductor substrate, and the semiconductor substrate and the rolls are rotated, while pure water or deionized water is flowed, thereby performing cleaning of the semiconductor substrate.

After completion of the primary cleaning, the semiconductor substrate is transferred by the fourth robot 834 to the second polishing apparatus 822 where the barrier layer on the semiconductor substrate is polished. At this time, desired abrasive grains or the like are used, but fixed abrasive may be used in order to prevent dishing and enhance flatness of the surface. After completion of secondary polishing, the semiconductor substrate is transferred by the fourth robot 834 again to the first cleaning unit 815 where scrub-cleaning is performed. After completion of cleaning, the semiconductor substrate is transferred by the fourth robot 834 to the second substrate reversing machine 844 where the semiconductor substrate is reversed to cause the plated surface to be faced upward, and then the semiconductor substrate is placed on the substrate temporary placing table 845 by the third robot 833.

The semiconductor substrate is transferred by the second robot 832 from the substrate temporary placing table 845 to the cap plating unit 817 where Ni—B plating is applied onto the copper surface with the aim of preventing oxidation of copper due to the atmosphere. The semiconductor substrate to which cap plating has been applied is carried by the second robot 832 from the cap plating unit 817 to the third film thickness measuring instrument 846 where the thickness of the copper film is measured. Thereafter, the semiconductor substrate is carried by the first robot 831 into the second cleaning unit 818 where it is cleaned with pure water or deionized water. The semiconductor substrate after completion of cleaning is returned into the cassette 820a placed on the loading/unloading section 820.

The aligner and film thickness measuring instrument 841 and the aligner and film thickness measuring instrument 842 perform positioning of the notch portion of the substrate and measurement of the film thickness.

Annealing treatment performed before the CMP process and after plating has a favorable effect on the subsequent CMP treatment and on the electrical characteristics of interconnection. Observation of the surface of broad interconnection (unit of several micrometers) after the CMP treatment without annealing showed many defects such as microvoids, which resulted in an increase in the electrical resistance of the entire interconnection. Execution of annealing ameliorated the increase in the electrical resistance. In the presence of annealing, thin interconnection showed no voids. Thus, the degree of grain growth is presumed to be involved in these phenomena. That is, the following mechanism can be speculated: Grain growth is difficult to occur in thin interconnection. In broad interconnection, on the other hand, grain growth proceeds in accordance with annealing treatment. During the process of grain growth, ultra-fine pores in the plated film, which are too small to be seen by the SEM (scanning electron microscope), gather and move upward, thus forming microvoid-like depressions in the upper part of the interconnection. The annealing conditions in the annealing unit 814 are such that hydrogen (2% or less) is added in a gas atmosphere, the temperature is in the range of 300° C. to 400° C., and the time is in the range of 1 to 5 minutes. Under these conditions, the above effects were obtained.

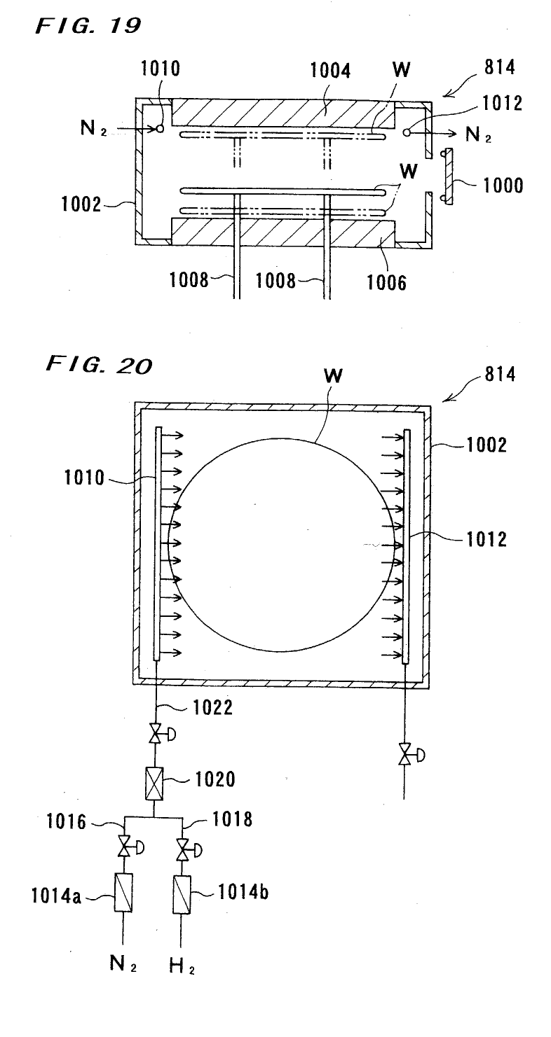

FIGS. 19 and 20 show the annealing unit 814. The annealing unit 814 comprises a chamber 1002 having a gate 1000 for taking in and taking out the semiconductor substrate W, a hot plate 1004 disposed at an upper position in the chamber 1002 for heating the semiconductor substrate W to e.g. 400° C., and a cool plate 1006 disposed at a lower position in the chamber 1002 for cooling the semiconductor substrate W by, for example, flowing a cooling water inside the plate. The annealing unit 814 also has a plurality of vertically movable elevating pins 1008 penetrating the cool plate 1006 and extending upward and downward therethrough for placing and holding the semiconductor substrate W on them. The annealing unit further includes a gas introduction pipe 1010 for introducing an antioxidant gas between the semiconductor substrate W and the hot plate 1004 during annealing, and a gas discharge pipe 1012 for discharging the gas which has been introduced from the gas introduction pipe 1010 and flowed between the semiconductor substrate W and the hot plate 1004. The pipes 1010 and 1012 are disposed on the opposite sides of the hot plate 1004.

The gas introduction pipe 1010 is connected to a mixed gas introduction line 1022 which in turn is connected to a mixer 1020 where a N₂ gas introduced through a N₂ gas introduction line 1016 containing a filter 1014a, and a H₂ gas introduced through a H₂ gas introduction line 1018 containing a filter 1014b, are mixed to form a mixed gas which flows through the line 1022 into the gas introduction pipe 1010.

In operation, the semiconductor substrate W, which has been carried in the chamber 1002 through the gate 1000, is held on the elevating pins 1008 and the elevating pins 1008 are raised up to a position at which the distance between the semiconductor substrate W held on the lifting pins 1008 and the hot plate 1004 becomes e.g. 0.1-1.0 mm. In this state, the semiconductor substrate W is then heated to e.g. 400° C. through the hot plate 1004 and, at the same time, the antioxidant gas is introduced from the gas introduction pipe 1010 and the gas is allowed to flow between the semiconductor substrate W and the hot plate 1004 while the gas is discharged from the gas discharge pipe 1012, thereby annealing the semiconductor substrate W while preventing its oxidation. The annealing treatment may be completed in about several tens of seconds to 60 seconds. The heating temperature of the substrate may be selected in the range of 100-600° C.

After the completion of the annealing, the elevating pins 1008 are lowered down to a position at which the distance between the semiconductor substrate W held on the elevating pins 1008 and the cool plate 1006 becomes e.g. 0-0.5 mm. In this state, by introducing a cooling water into the cool plate 1006, the semiconductor substrate W is cooled by the cool plate to a temperature of 100° C. or lower in e.g. 10-60 seconds. The cooled semiconductor substrate is sent to the next step.

A mixed gas of N₂ gas with several % of H₂ gas is used as the above antioxidant gas. However, N₂ gas may be used singly.

### EXAMPLE 1

Edge-etching and back surface-cleaning of a substrate were carried out using the substrate processing apparatus (edge-etching apparatus) shown in FIG. 1. A substrate W composed of a silicon wafer, and a 100 nm-thick oxide film (SiO₂), a 30 nm-thick TaN film, a 150 nm-thick sputtered copper film as a seed layer and a 1000 nm-thick plated copper film, formed in this order on the silicon wafer, was used.

First, while rotating the substrate W, which was held with its front surface facing upward by the substrate holder 10, pure water was supplied from the front surface nozzle 14 and the back surface nozzle 16 to the front and back surfaces of the substrate W so as to wet the substrate W. By thus wetting the substrate W with pure water in advance, an etching chemical liquid can be spread over the substrate uniformly from the start of its supply.

Next, the pivot arm 22 in the retreat position was moved to above the center of the surface of the substrate W, and was then lowered close to the substrate W. Thereafter, while rotating the substrate W, DHF (1.0 L/min) was supplied from the center nozzle 24 to the substrate for protection of the circuit-forming surface and removal of a spontaneous copper oxide film. The DHF had been heated and its temperature was controlled, and the heated DHF was supplied to the substrate W so as to heat the substrate W uniformly. Immediately thereafter, H₂O₂ (about 30 mL/min) at room temperature or lower, as an oxidizing acid, was supplied from the edge nozzle 26 to a portion of the substrate at 3 mm distance from the end surface of the substrate, thereby etching and removing the copper film in the edge portion. At the same time, H₂O₂ at room temperature or lower was supplied from one back surface nozzle 16 and DHF was supplied from the other back surface nozzle 18 alternately at a rate of 1 L/min, thereby effecting etching of the back surface of the substrate.

After completion of the etching, supply of the etching liquid from the edge nozzle 26 and the back surface nozzles 16, 18 was stopped. Almost at the same time, supply of pure water from the front surface nozzle 14 and the back surface nozzle 16 was started to carry out rinsing of the substrate for 20 seconds. After the pure water rinsing, the substrate was rotated at a high speed of 2000 rpm for drying.

By the heating of the substrate W by the heated DHF as a heated fluid, as compared to the case of not heating the substrate, the just etching time for etching the copper film, as determined by visual observation, can be shortened from 20 seconds to 10 seconds. Further, because of the shortened processing time, the amount of chemicals used can be reduced.

### EXAMPLE 2

Using the substrate processing apparatus (edge-etching apparatus) shown in FIG. 1 and using a substrate composed of a silicon wafer and a 100 nm-thick oxide film (SiO₂) formed on the wafer, etching of the oxide film in the edge portion and in the back surface of the substrate and cleaning of the back surface of the substrate were carried out simultaneously.

The apparatus was operated in the same manner as in Example 1 except that etching was carried out by supplying heated pure water from the center nozzle 24, and supplying DHF as a SiO₂-etching liquid from the edge nozzle 26 and the back surface nozzle 16.

By thus heating pure water and controlling the temperature, and supplying the heated pure water to the substrate W so as to heat the substrate W uniformly, the etching rate can be increased as compared to the case of not heating the pure water. This is true of the following Examples 4 to 9.

### EXAMPLE 3

Embedding of copper into trenches for interconnects formed in a substrate was carried out using the substrate processing apparatus (electroless plating apparatus) shown in FIG. 2. A substrate W was employed which had been prepared by forming a 100 nm-thick oxide film (SiO₂), a 30 nm-thick TaN film and a 150 nm-thick sputtered copper film as a seed layer in this order on a silicon wafer, and then removing the sputtered copper film on the surface of the wafer by using a CMP apparatus.

While rotating the substrate W, which was held with its front surface facing upward by the substrate holder 32, the plating solution 34 was poured from the center nozzle 36 onto the upper surface (to-be-plated surface) of the substrate W, thereby forming a plated film on the seed layer 7 in the trenches for interconnects. During the plating processing, heated ultrapure water was jetted toward the back surface of the substrate W so as to heat the entire substrate uniformly with the aid of the rotation of the substrate W. The heating of the substrate increased the plating rate and enhanced uniformity of the plated film thickness over the entire surface of the substrate.

### EXAMPLE 4

Using the substrate processing apparatus (edge-etching apparatus) shown in FIG. 1 and using a substrate composed of a silicon wafer, and a 300 nm-thick oxide film (SiO₂), formed on the front and back surfaces of the wafer, a 30 nm-thick Ti film, a 50 nm-thick TiN film and a 100 nm-thick Ru film, formed in this order on the wafer, etching of the ruthenium (Ru) film in the edge portion of the substrate and cleaning of the back surface of the substrate were carried out simultaneously.

The apparatus was operated in the same manner as in Example 1 except that etching and cleaning were carried out by supplying heated pure water from the center nozzle 24, NaClO at room temperature or lower as a Ru-etching liquid from the edge nozzle 26, and DHF at room temperature or lower as a SiO₂-etching liquid from the back surface nozzle 16. The use of NaClO at room temperature or lower can prevent its decomposition.

### EXAMPLE 5

Using the substrate processing apparatus (edge-etching apparatus) shown in FIG. 1 and using the same substrate as in Example 4, but having the Ru film, formed e.g. by CVD, also in the back surface of the substrate, etching of the Ru film in the edge portion of the substrate and etching of the Ru film in the back surface of the substrate were carried out simultaneously.

The apparatus was operated in the same manner as in Example 1 except that etching was carried out by supplying heated pure water from the center nozzle 24, and supplying NaClO at room temperature or lower as a Ru-etching liquid from the edge nozzle 26 and the back surface nozzle 16.

### EXAMPLE 6

Using the substrate processing apparatus (edge-etching apparatus) shown in FIG. 1 and using a substrate composed of a silicon wafer, and a 300 nm-thick oxide film (SiO₂), formed on the front and back surfaces of the wafer, a 30 nm-thick Ti film, a 50 nm-thick TiN film and a 100 nm-thick Co film, formed in this order on the wafer, etching of the cobalt (Co) film in the edge portion of the substrate and cleaning of the back surface of the substrate were carried out simultaneously.

The apparatus was operated in the same manner as in Example 1 except that etching and cleaning were carried out by supplying heated pure water from the center nozzle 24, a mixture of HCl and H₂O₂ at room temperature or lower as a Co-etching liquid from the edge nozzle 26, and DHF at room temperature or lower as a SiO₂-etching liquid from the back surface nozzle 16.

### EXAMPLE 7

Using the substrate processing apparatus (edge-etching apparatus) shown in FIG. 1 and using a substrate composed of a silicon wafer, and a 300 nm-thick oxide film (SiO₂), formed on the front and back surfaces of the wafer, a 30 nm-thick Ti film and a 50 nm-thick TiN film, formed in this order on the wafer, etching of the TiN film in the edge portion of the substrate and cleaning of the back surface of the substrate were carried out simultaneously.

The apparatus was operated in the same manner as in Example 1 except that etching and cleaning were carried out by supplying heated pure water from the center nozzle 24, a mixture of HCl and H₂O₂ at room temperature or lower as a TiN-etching liquid from the edge nozzle 26, and DHF at room temperature or lower as a SiO₂-etching liquid from the back surface nozzle 16.

### EXAMPLE 8

Using the substrate processing apparatus (edge-etching apparatus) shown in FIG. 1 and using a substrate composed of a silicon wafer, and a 300 nm-thick oxide film (SiO₂), formed on the front and back surfaces of the wafer, and a 100 nm-thick SiN film, formed in this order on the wafer, etching of the SiN film in the edge portion of the substrate and cleaning of the back surface of the substrate were carried out simultaneously.

The apparatus was operated in the same manner as in Example 1 except that etching and cleaning were carried out by supplying heated pure water from the center nozzle 24, DHF at room temperature or lower as a SiN-etching liquid from the edge nozzle 26, and DHF at room temperature or lower as a SiO₂-etching liquid from the back surface nozzle 16.

### EXAMPLE 9

Using the substrate processing apparatus (edge-etching apparatus) shown in FIG. 1 and using a substrate composed of a silicon wafer, and a 300 nm-thick oxide film (SiO₂), formed on the front and back surfaces of the wafer, and a 30 nm-thick TaN film, formed in this order on the wafer, etching of the TaN film in the edge portion of the substrate and cleaning of the back surface of the substrate were carried out simultaneously.

The apparatus was operated in the same manner as in Example 1 except that etching and cleaning were carried out by supplying heated pure water from the center nozzle 24, a mixture of DHF and H₂O₂ at room temperature or lower as a TaN-etching liquid from the edge nozzle 26, and DHF at room temperature or lower as a SiO₂-etching liquid from the back surface nozzle 16.

As described hereinabove, the present invention makes it possible to carry out processing of a substrate while the substrate itself is kept heated. This can uniformly increase the rate of processing of the substrate, such as etching and plating and, in the case of plating, can form a plated film having a uniform film thickness easily and quickly.

What is claimed is:

1. A substrate processing apparatus, comprising:
a substrate holder for holding and rotating a substrate; and
a heated fluid supply section for bringing a heated fluid at a controlled temperature into contact with the substrate, which is held and rotated by the substrate holder, so as to control the temperature of the substrate.

2. The substrate processing apparatus according to claim 1, wherein the heated fluid is a heated liquid.

3. The substrate processing apparatus according to claim 2, wherein the liquid is pure water.

4. The substrate processing apparatus according to claim 1, further comprising a fluid supply section for supplying a fluid to an arbitrary region of the substrate held by the substrate holder.

5. A substrate processing apparatus, comprising:
a substrate holder for holding and rotating a substrate, said apparatus carrying out processing of the substrate by simultaneously bringing a plurality of fluids into contact with the substrate which is held and rotated by the substrate holder;
wherein at least one of said plurality of fluids is a heated fluid and the remainder is a fluid nearly at room temperature or lower.

6. The substrate processing apparatus according to claim 5, wherein the heated fluid is a heated liquid.

7. The substrate processing apparatus according to claim 6, wherein the liquid is pure water.

8. A substrate processing method, comprising:
carrying out processing of a substrate while controlling the temperature of the substrate by bring a heated fluid at a controlled temperature into contact with the substrate while holding and rotating the substrate.

9. The substrate processing method according to claim 8, wherein the processing of the substrate is edge-etching and/or substrate cleaning.

10. The substrate processing method according to claim 8, wherein the processing of the substrate is plating.

11. A substrate processing method, comprising:
bringing a fluid nearly at room temperature or lower into contact with a substrate while rotating and holding the substrate to carry out processing of the substrate while, at the same time, bringing a heated fluid at a controlled temperature into contact with the substrate so as to control the temperature of the substrate.

12. The substrate processing method according to claim 11, wherein the processing of the substrate is edge-etching and/or substrate cleaning.

13. The substrate processing method according to claim 11, wherein the processing of the substrate is plating.
